(19) United States
(12) Patent Application Publication
(10) Pub. No.: US 2017/0092558 A1
(43) Pub. Date: Mar. 30, 2017

(54) ENHANCEMENT OF CHIP THERMAL PERFORMANCE THROUGH SILICON THERMAL CONDUCTIVITY MODULATION

(71) Applicant: QUALCOMM Incorporated, San Diego, CA (US)

(72) Inventors: Arpit MITTAL, San Diego, CA (US); Mehdi SAEIDI, San Diego, CA (US); Kambiz SAMADI, San Diego, CA (US)

(21) Appl. No.: 14/864,951

(22) Filed: Sep. 25, 2015

(51) Int. Cl. H01L 23/34; H01L 25/065; H01L 23/528; H01L 23/367; H01L 25/16

(52) U.S. Cl. CPC H01L 23/34; H01L 23/367; H01L 25/16; H01L 23/5286; H01L 25/0657; H01L 2225/06589

(57) ABSTRACT

An integrated circuit includes inter-digital transducers in a silicon die, where the inter-digital transducers are driven to excite phonons in the silicon die to modulate its thermal conductivity. The thermal conductivity may be increased by exciting acoustic phonons in the silicon die, so that heat dissipation is improved, or the thermal conductivity may be decreased by exciting optical phonons so that heat dissipation is reduced. In conjunction with power management, the thermal conductivity is increased or decreased depending upon the power states of various functional units in the silicon die and depending upon various temperature sensors.

### FIELD OF DISCLOSURE

Embodiments are directed to electronic integrated circuits, and more particularly to removing heat in electronic integrated circuits.

### BACKGROUND

As VLSI technology scales to smaller dimensions, thermal issues are becoming a dominant factor in the performance, reliability, and cost of high-performance integrated circuits. Management of these issues is a key factor in the development of next-generation microprocessors, integrated networks, and other highly integrated systems. The difficulty in removing heat efficiently is currently a major stumbling block towards further miniaturization and advancement of electronic, optoelectronic, and micro-electro-mechanical system (MEMS) devices. Efficiently removing heat from such devices is a daunting task, and overheating is a common cause of device failure.

### SUMMARY

Embodiments of the invention are directed to systems and methods for the enhancement of chip thermal performance through silicon thermal conductivity modulation.

In an embodiment, a system comprises: a silicon die having an active layer, the active layer comprising a processor; a power rail to provide current to the processor; a temperature sensor to provide a signal indicative of a temperature of the processor; and at least one functional unit; at least one transducer; and a controller to drive the at least one transducer to excite acoustic phonons or optical phonons in the silicon die.

In an embodiment, a method modulates thermal conductivity in a silicon die having an active layer with a processor and at least one functional unit, the method comprising: driving at least one transducer to excite acoustic phonons in a region in the silicon die overlapping the at least one functional unit provided the at least one functional unit is in a power collapse state, a signal indicates a temperature of the processor is greater than a first threshold, and a current in a power rail to the processor is greater than a second threshold.

In an embodiment, a non-transitory computer-readable media has stored instructions to program a controller to modulate thermal conductivity of a silicon die, the silicon die having an active layer comprising a processor, a power rail to provide current to the processor, a temperature sensor to provide a signal indicative of a temperature of the processor, and at least one functional unit, the stored instructions when executed by the controller to perform a method comprising: driving at least one transducer to excite acoustic phonons in a region in the silicon die overlapping the at least one functional unit but not overlapping the processor provided the at least one functional unit is in a power collapse state, the signal indicates the temperature of the processor is greater than a first threshold, and the current in the power rail to the processor is greater than a second threshold.

For some embodiments, the at least one transducer may include one or more inter-digital transducers.

In an embodiment, a system comprises: a silicon die having an active layer, the active layer comprising a processor; a power rail to provide current to the processor; a temperature sensor means for providing a signal indicative of a temperature of the processor; and at least one functional unit; an exciter means for exciting acoustic phonons or optical phonons in the silicon die; and a controller means for controlling the exciter means.

### BRIEF DESCRIPTION OF THE DRAWINGS

The accompanying drawings are presented to aid in the description of embodiments of the invention and are provided solely for illustration of the embodiments and not limitation thereof.

FIG. 1A is a cross-sectional view of monolithic integration of an active silicon layer and inter-digital transducers on the same silicon substrate.

FIG. 1B is a cross-sectional view of face-to-back (F2B) integration of an active silicon layer and inter-digital transducers.

FIG. 1C is a cross-sectional view of face-to-face (F2F) integration of an active silicon layer and inter-digital transducers.

FIG. 2 is a schematic of a controller and inter-digital transducers with several functional units.

FIG. 3 illustrates regions above the active layer of the silicon die for which the corresponding thermal conductivity may be modulated by inter-digital transducers.

FIG. 4 is a flow diagram illustrating a general method for modulating thermal conductivity.

FIG. 5 illustrates a control flow for the controller of the inter-digital transducers to modulate thermal conductivity.

FIG. 6 is a generalization of the control flow illustrated in FIG. 5.

FIG. 7 illustrates a control flow for the controller of the inter-digital transducers to modulate thermal conductivity.

FIG. 8 illustrates a control flow for the controller of the inter-digital transducers to modulate thermal conductivity.

FIG. 9 illustrates a system architecture of a smartphone or tablet in which an embodiment finds application.

### DETAILED DESCRIPTION

Embodiments are disclosed in the following description and related drawings directed. Alternate embodiments may be devised without departing from the scope of the claims. Additionally, well-known elements of the invention will not be described in detail or will be omitted so as not to obscure the relevant details of the embodiments. The term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

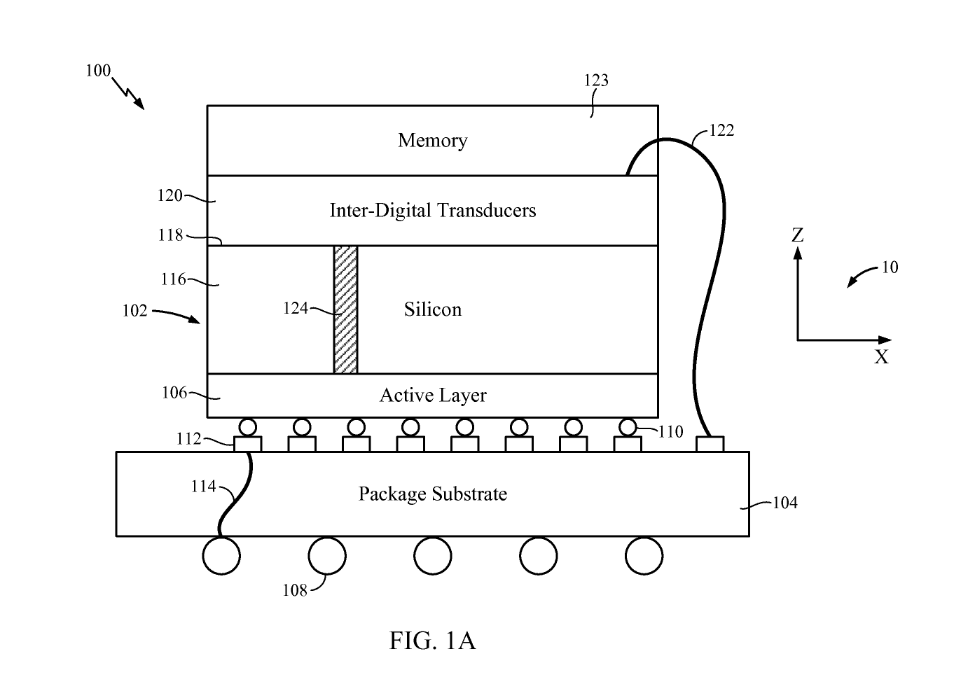

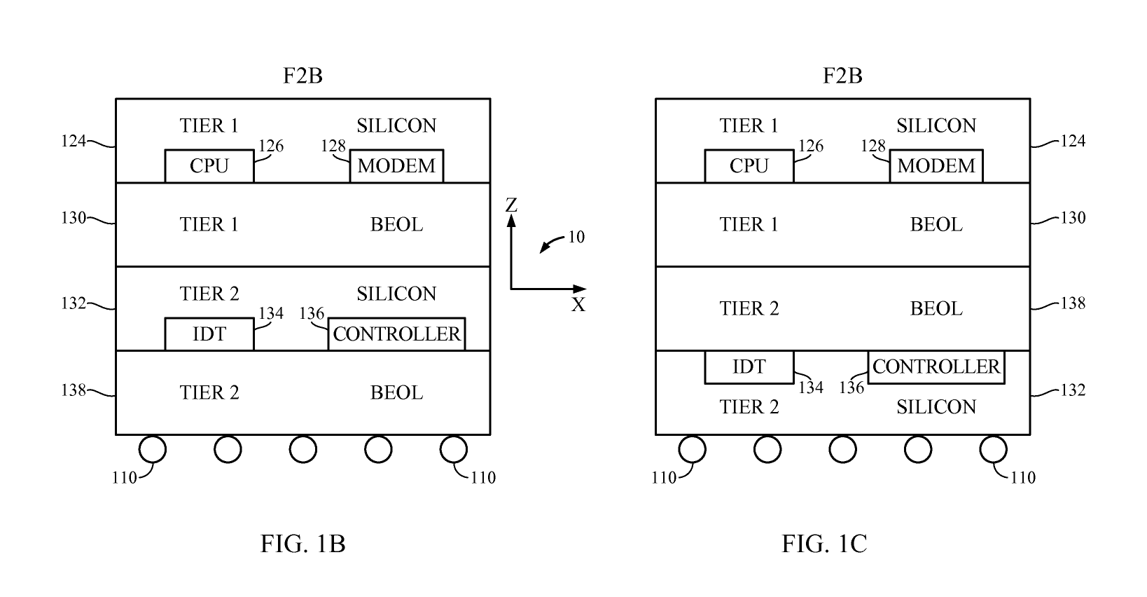

FIG. 1A is a cross-sectional view of an integrated circuit 100, also referred to herein as a packaged integrated circuit or system-on-chip (SoC). Standard and well-known techniques may be employed to couple the silicon die 102 to the package substrate 104. The active layer 102 of the silicon die 102 is electrically coupled to contacts 108 on the package substrate 104 by way of solder balls 110 on the active layer 106 in electrical contact with package contacts 112 and vias 114. The silicon bulk 116 of the silicon die 102 upon which the active layer 106 is fabricated includes a backside 118. Formed on the backside 118 of the silicon die 102 is a set of one or more inter-digital transducers (IDTs), represented by the inter-digital transducer (IDT) 120.

The stacked memory 123 is coupled to the top of the silicon 116, where for example the stacked memory 123 may be fabricated on a silicon die separate from that of the silicon 102 and electrically bonded to various contacts formed on the silicon die 116. (For ease of illustration, the electrical connections of the stacked memory 123 to the integrated circuits formed on the silicon die 116 are not shown.)

For simplicity, the IDT 120 are illustrated as a monolithic block on top of the backside 118, it being understood that the IDT 120 are three-dimensional structures formed on the backside 118 by photolithography techniques. So as not to obscure the various illustrated components, FIG. 1A does not include various fill material as well as the package enclosure that would be present in a typical packaged integrated circuit.

Electrical power provided to the IDT 120, as well as other associated functional units to be described shortly, may be provided by way of electrical wires, such as the electrical wire 122, or by way of through-silicon vias, such as for example the through-silicon via 124. The electrical wire 122 may be electrically coupled to one of the solder balls 110, and the through-silicon via 124 may be electrically coupled to a power rail on the active layer 106.

To provide relative orientations of the views represented in FIGS. 1A and 1n some of the figures to follow, the right-handed coordinate system 10 is illustrated. The coordinate system 10 is shown with its x-axis and z-axis lying in the page of the drawing with the x-axis parallel to the package substrate 104 and the z-axis pointing along the thickness of the silicon die 102 and perpendicular to the package substrate 104. In FIG. 1A, the y-axis of the coordinate system 10 points into the page of the drawing.

FIG. 1B represents a face-to-back (F2B) implementation. Fabricated on a silicon die is the tier 1 layer 124 in which various functional units are integrated, such as for example the central processing unit (CPU) 126 and the modem 128. More generally, the CPU 126 may be any kind of processor or multiple processors. These two functional units merely serve as examples, and in practice other functional units for various systems are fabricated in the tier 1 layer 124. The tier 1 BEOL (back-end of-line) layer 130 comprises various interconnects to provide electrical coupling to the functional units fabricated in the tier 1 layer 124.

Fabricated on a silicon die is the tier 2 layer 132, comprising the IDT 134 and the controller 136. The controller 136 controls the IDT 134, and its operations will be discussed in more detail later. The tier 2 BEOL layer 138 comprises various interconnects to provide electrical coupling to the tier 2 layer 132, and the solder balls 110 provide electrical connections to a package substrate as discussed with respect to FIG. 1A. As in FIG. 1A, FIG. 1B does not include various fill material as well as the package enclosure that would be present in a typical packaged integrated circuit.

FIG. 1C represents a face-to-back (F2B) implementation, with similar components as in FIG. 1B, but where the tier 1 BELO layer 130 is bonded to the tier 2 BELO layer 138. The components in FIG. 1C are labeled with the same numerals as their corresponding components in FIG. 1B, so that much of the above description regarding FIG. 1B is applicable.

The embodiments illustrated in FIGS. 1A, 1B, and 1C show the IDTs, for example the IDT 118 and the IDT 134, in a silicon layer separate from other silicon layers containing various functional units. For some embodiments, one or more IDTs may be integrated on the same silicon layer in which the various functional units are integrated.

The packaged integrated circuits represented by the embodiments of FIGS. 1A, 1B, and 1C may find application in a wide range of electronic systems, such as for example a smartphone or tablet, where functional units fabricated in the active layer 106 perform some or all of the functions implemented in a smartphone or tablet. Embodiments are described where the controller 136 controls the IDT 120 or IDT 134 to modulate the thermal conductivity of the packaged integrated circuit to mitigate performance issues associated with undesirable heating of the packaged integrated circuit or the device (e.g., a smartphone or tablet) in which the packaged integrated circuit is utilized.

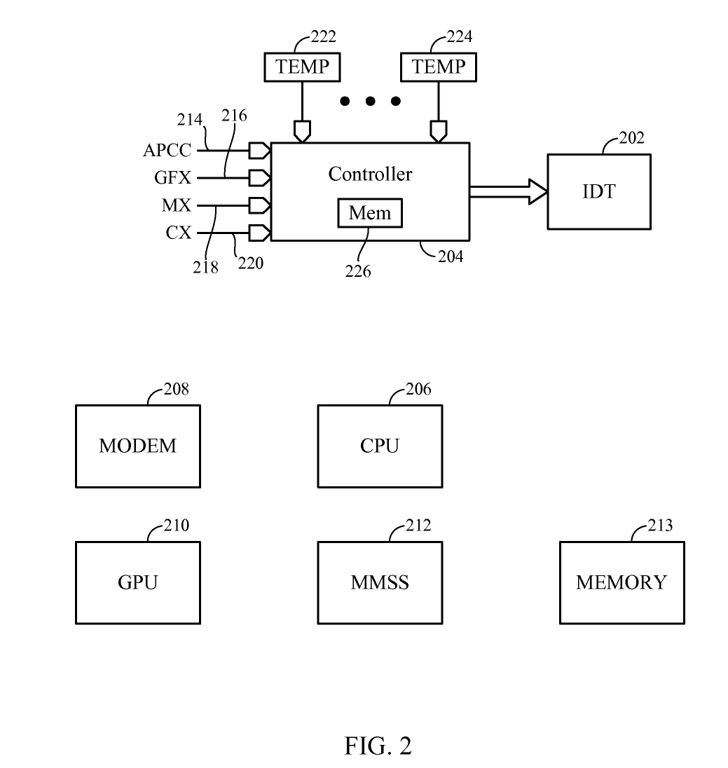

FIG. 2 is a schematic illustrating the IDT 202, the controller 204, and five functional units: the CPU 206, the modem 208, the graphics processor unit (GPU) 210, the multi-media sub-system (MMSS) 212, and the memory 213. The MMSS 212 may include various functional units, such as for example a video codec, an audio codec, and an image processor for a camera, to name just a few examples. The memory 213 may be, for example, the stacked memory 123. The various components illustrated in FIG. 2 may reside in one or more silicon layers as described with respect to the embodiments illustrated in FIGS. 1A, 1B, and 1C.

The controller 204 monitors several power rails and temperature sensors. FIG. 2 illustrates four power rails: APCC 214 denotes a power rail for the CPU 206, GFX denotes a power rail for the GPU 216, MX 218 denotes a power rail for the memory 213, and CX 220 denotes a power rail for the MMSS 212. The power rail CX 220 may also denote a power rail for the modem 208. The controller 204 may monitor the voltage or current in these power rails. A plurality of temperature sensors provide their corresponding output signals to the controller 204, where for ease of illustration two such temperature sensors are shown, labeled 222 and 224. The temperature sensors may measure the temperature of some or all of the functional units, as well as the skin temperature of the packaged integrated circuit represented in FIGS. 1A, 1B, and 1C, or the device in which the packaged integrated circuit is used.

The controller 204 may be programmable, where some or all of the instructions programming the controller 204 are stored in the memory 226, where the memory 226, denoted as “Mem 226” in FIG. 2, is integrated in the controller 204. The memory 226 is be understood to be sufficiently generalized so that the instructions stored in the memory 226 for programming the controller 204 may be considered as software or firmware. In some embodiments, the controller 204 may be integrated with the CPU 206, or in some embodiments the CPU 206 may perform the functionality of the controller 204. Thus, the representation of the controller 204 as a functional unit separate from the CPU 206 may be viewed as a logical (functional) representation and not an indication that a physical realization requires a separate system for the controller 204.

The IDT 120 or IDT 134 in FIGS. 1A, 1B, and 1C may be fabricated such that when looking down into the z-axis, the footprint of the IDT 120 or IDT 134 when projected onto the active layer 106 or the tier 1 layer 124 covers a relatively large portion of the active layer 106 or the tier 1 layer 124 in which the various functional units (e.g., the CPU 206, the modem 208, the GPU 210, and the MMSS 2112) are fabricated. Referring to the numeric labels of FIG. 2, the IDT 202 may be configured so that the controller 204 may control various portions of the IDT 202, where the footprint of these controlled portions when projected onto the active layer containing the various functional units define a grid-like array. In this way, the thermal conductivity of the silicon die 102 can be modified in various localized regions.

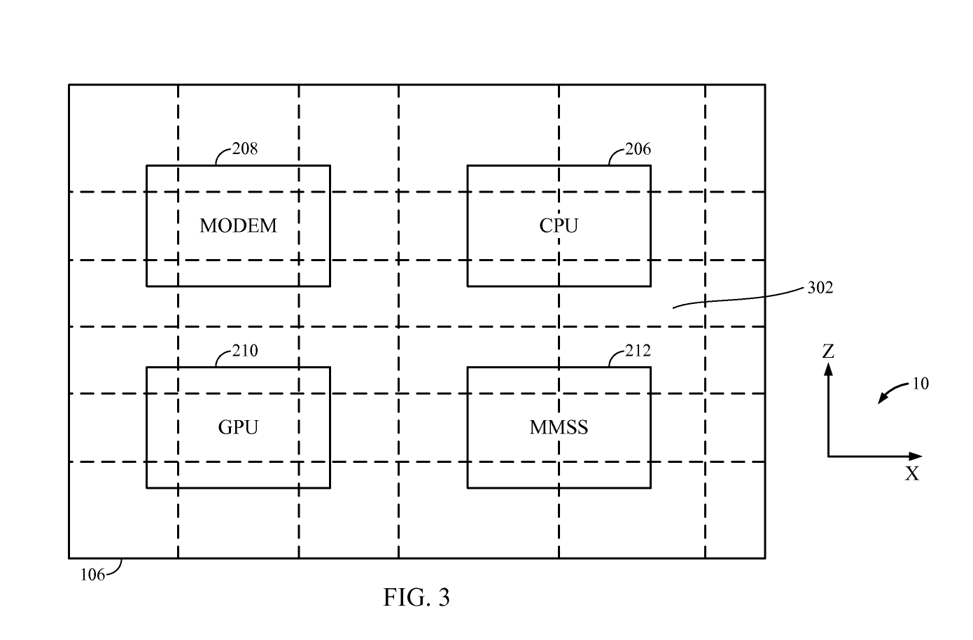

FIG. 3 illustrates an embodiment where the IDT 202 is configured so that the controller 204 may control the IDTs in any one of 36 regions defined by the dashed lines, the region 302 serving as one example. Note the relative orientation of the coordinate system 10 in FIG. 3, so that the view is into the z-axis. In a sense, the active layer 106 is conceptually divided into 36 rectangles defined by the dashed lines, each rectangle a projection along the z-axis of a rectangular prism volume onto the active layer of functional units. In an embodiment, the controller 204 may control any number of such regions, where for example only that part of the IDT 202 in the rectangles overlapping the CPU 206 may be activated so as to modulate the thermal conductivity of the silicon die 102 confined to a region above the CPU 206.

Embodiments modulate the thermal conductivity of the silicon die 102 by exciting acoustic or optical phonons (modes). Exciting acoustic phonons in a crystal lattice increases its thermal conductivity, whereas exciting optical phonons decreases its thermal conductivity. In the case of exciting acoustic phonons, it is preferable to excite the acoustic phonons having a relatively large group velocity to bring about a relatively large increase in thermal conductivity; whereas in the case of exciting optical phonons, it is preferable to excite the optical phonons having a relatively small group velocity. For example in silicon, for phonon dispersion in the [1 0 0] direction, lateral acoustic phonons have higher group velocity than transverse acoustic phonons, whereas transverse optical phonons have smaller group velocity than longitudinal optical phonons.

An IDT is a well-known structure that has been employed for many years in SAW (Surface Acoustic Wave) devices. In a conventional SAW device, a periodic metallic structure of inter-digital electrodes (fingers) forming the IDT is formed or deposited on a uniformly polarized piezoelectric crystal or film. Electrical energy provided to the IDT generates an electric field that is coupled by way of the piezoelectric effect to surface acoustic waves (or Rayleigh waves) propagating in the piezoelectric crystal or film. Other types of waves, for example horizontally polarized surface waves, may be generated as well.

The phase velocity of the piezoelectric material and the spacing between the electrodes (or fingers) of the IDT determine the center frequency of the electrical signal for driving the IDT, where f=ν/λ, with f representing center frequency, ν representing the phase velocity, and λ representing the distance between the IDT fingers. A typical frequency for exciting the IDT may be in the microwave region, such as for example on the order of 1 GHz. Structures other than periodic metallic electrodes may be employed, such as for example forming oppositely polarized ferroelectric domains within the piezoelectric material itself. In describing the embodiments, it is to be understood that an IDT may include the piezoelectric material upon which the inter-digital electrodes or fingers are formed.

With an IDT formed on a silicon die, the energy of the surface acoustic waves generated on the piezoelectric material of the IDT is coupled to the lattice of the silicon die, thereby generating phonons, such as for example acoustic phonons. Multiple acoustic phonon interactions can lead to the generation of optical phonons. For example, the phonon-phonon interaction of two acoustic phonons of frequencies ω₁ and ω₂ can lead to the generation of an optical phonons at the frequency ω₃, where ω₁+ω₂=ω₃.

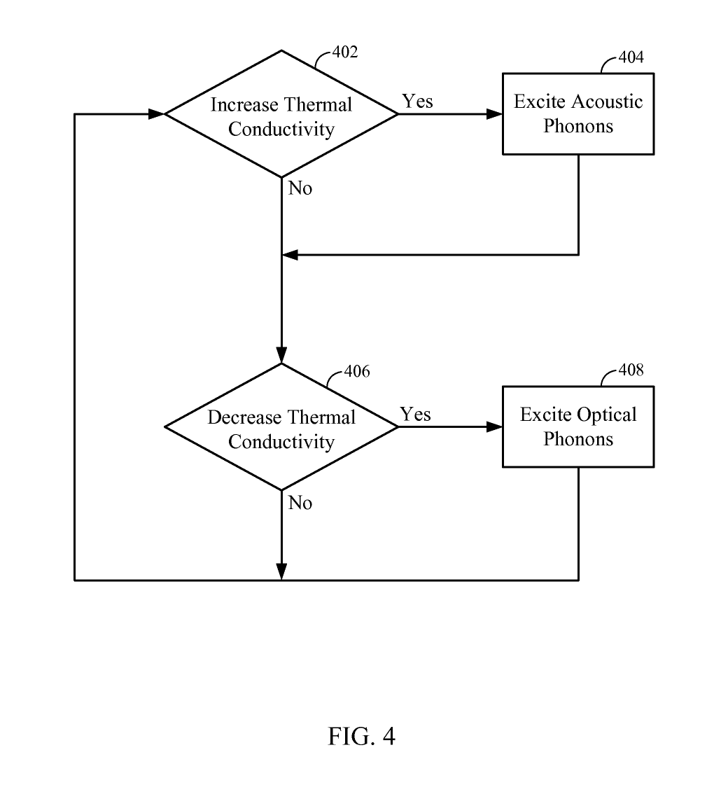

FIG. 4 illustrates a general control flow for the controller 204 to modulate thermal conductivity. If in the action 402 the controller 204 determines that the thermal conductivity should be increased, then in the action 404 the controller 204 drives the IDT 202 to excite acoustic phonons. If in the action 406 the controller 204 determines that thermal conductivity should be decreased, then in the action 408 the controller 204 drives the IDT 202 to excite optical phonons.

In practice, there will be both acoustic and optical phonons excited in a crystal lattice. That is, exciting one particular type of phonon mode will nevertheless excite other modes. Consequently, it is to be appreciated that in the action 404, the controller 204 excites predominantly acoustic phonons although some optical phonons will be excited. That is, acoustic phonons are excited in a crystal lattice to a much greater degree than optical phonons so that thermal conductivity is increased in the crystal lattice. Similarly, in the action 408, the controller 204 excites predominantly optical phonons, but where some acoustic phonons will nevertheless be excited. That is, optical phonons are exited in a crystal lattice to a much greater degree than acoustic phonons so that thermal conductivity is decreased in the crystal lattice.

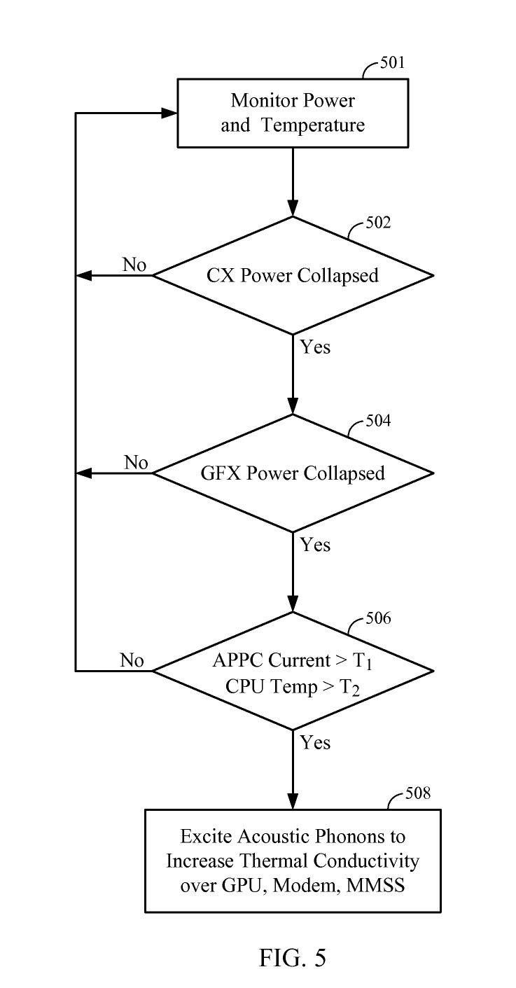

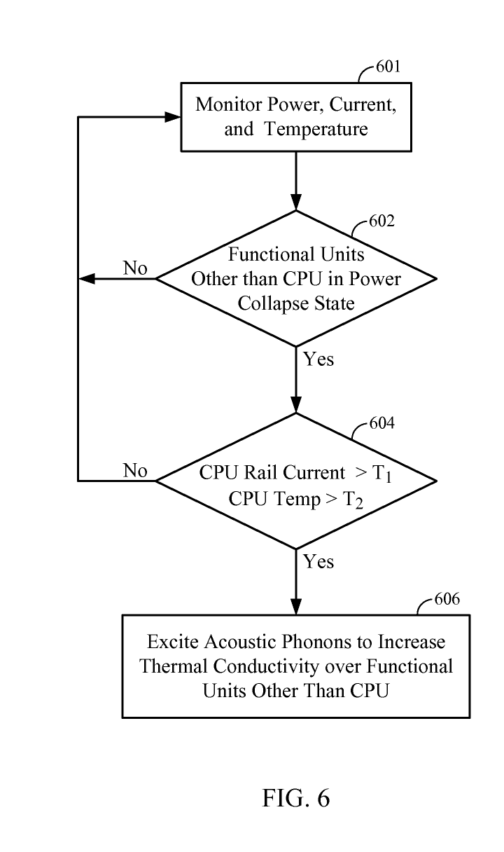

The controller 204, based upon the inputs illustrated in FIG. 2, may be programmed or configured (e.g., by software, firmware, or hardwired) to control the IDT 202 so as to mitigate performance issues associated with undesirable heating. Various control flows may be implemented. For example, a power management circuit may put various functional units into a power collapse state, but where the CPU 206 is kept operating. In that case, it may be desirable to increase thermal conductivity in those regions of the silicon die 102 not near the CPU 206 so that heat may be conducted laterally (along the x-axis relative to the coordinate system 10) away from the CPU 206 to other parts of the silicon die 102. FIG. 5 provides an example of such a control flow.

FIG. 5 illustrates a control flow for the controller 204 according to an embodiment. The controller 204 monitors power and temperature, indicated in the action 501. As indicated in the actions labeled 502 and 504, if the power rails CX 220 and GFX 216 are both in a power collapse state, then the action 506 determines whether the current in the power rail APPC 214 is greater than a first threshold and whether the temperature of the CPU 206 is greater than a second threshold. If these conditions are satisfied, then in the action 508 the controller 204 actuates various regions of the IDT 202 to excite acoustic phonons so as to increase the thermal conductivity over the modem 208, the GPU 210, and the MMSS 212, but not the CPU 206. For example, the controller 204 may actuate the regions of the IDT 202 defined by the dashed lines in FIG. 3 that overlap with the modem 208, the GPU 210, and the MMSS 212, so as to excite acoustic phonons. If the conditions in the actions 502, 504, or 506 are not satisfied, then as indicated in the action 501 of FIG. 5, the controller 204 continues to monitor power and temperature.

FIG. 6 is a generalization of the control flow represented in FIG. 5. The controller 204 monitors power and temperature, as indicated in the action 601. The Action 601 also recites that the controller 204 monitors current so as to indicate that monitoring current is one approach to monitoring power (assuming that the voltage drop is known), where it is to be understood that for other drawings, such as the action 501 in FIG. 5, monitoring power may include monitoring current. In the action 602, a determination is made as to whether functional units other than the CPU 206 are in a power collapse state; and in the action 604, a determination is made as to whether the current in the power rail for the CPU 206 is greater than a first threshold and the temperature of the CPU 206 is greater than a second threshold. If these conditions are satisfied, then in the action 606 the controller 204 controls the portions of the IDT 202 over the functional units other than the CPU 206 to excite acoustic phonons so as to increase thermal conductivity in those regions. If the conditions are not satisfied, then as indicated in the action 601, the controller 204 continues to monitor power (e.g., monitor current) and temperature.

In the action 604, comparing the temperature of the CPU 206 with the second threshold will in practice be performed by comparing a parameter, such as a value representing a voltage or a current, with some threshold, where the voltage or current is indicative of the temperature.

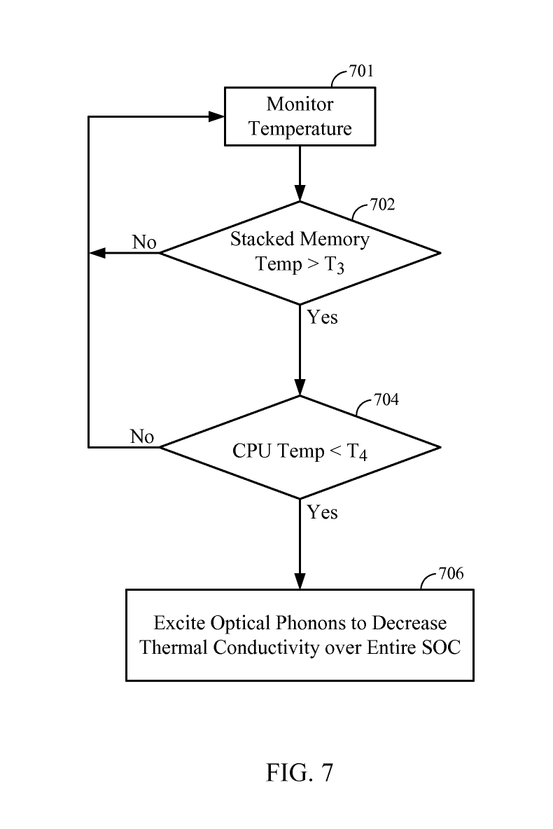

FIG. 7 provides another example of a control flow for the controller 204. The controller 204 monitors temperature, as indicated in the action 701. (In practice, the controller 204 also monitors other parameters, as discussed with respect to the previous drawings.) In the actions 702 and 704, if the stacked memory 123 has a temperature greater than a third threshold and if the CPU 206 has a temperature less than a fourth threshold, then in the action 706 the controller 204 causes the IDT 202 to excite optical phonons throughout the entire system-on-chip (SOC), for example the packaged integrated circuit 100 of FIG. 1A, so as to decrease thermal conductivity. The flow control illustrated in FIG. 7 may be appropriate when the stacked memory 123 is getting too hot but not the CPU 206. If the conditions indicated in the actions 702 or 704 are not satisfied, then control is brought back to the action 701 to indicate that the controller 204 continues to monitor temperature.

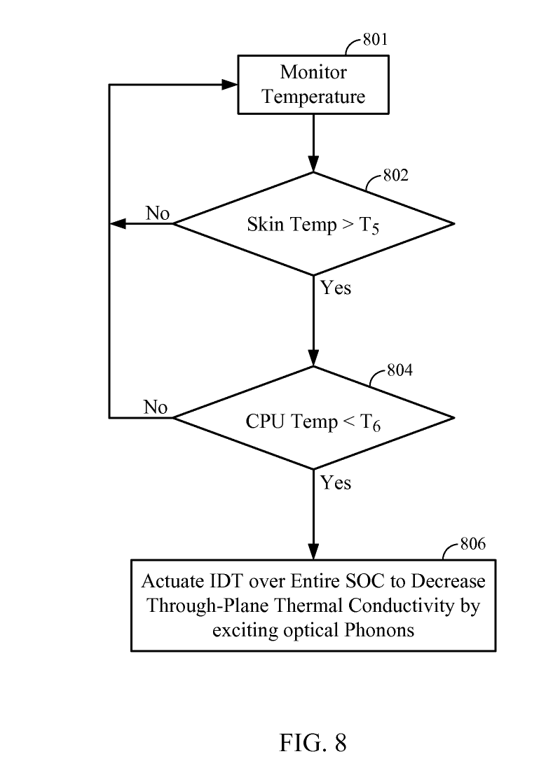

FIG. 8 provides another example of a control flow for the controller 204. As indicated in the action 801, the controller 204 monitors temperature (as well as perhaps other parameters). In the action 802, the skin temperature is compared to a fifth threshold. The skin temperature refers to the surface temperature of the integrated circuit package 100 represented in FIG. 1A and is indicative of the temperature of the device containing the packaged integrated circuit 100. If the skin temperature is too high, then the device may be uncomfortably hot to a user of the device. In the action 804, the temperature of the CPU 206 is compared to a sixth threshold.

If the action 802 determines that the skin temperature is greater than the fifth threshold and if the action 804 determines that the temperature of the CPU 206 is less than a sixth threshold, then in the action 806 the controller 204 actuates the IDT 202 to excite optical phonons to decrease the thermal conductivity throughout the SoC, in particular to decrease thermal flow in a direction perpendicular to the through-plane, where the through-plane refers to a plane parallel to the x-y plane of the coordinate system 10 as illustrated in FIG. 1A. In this way, less heat generated from the CPU 206 reaches the surface of the packaged integrated circuit 100. This is a viable approach because the action 804 determines that the CPU 206 is presently not too hot. If the conditions of the actions 802 or 804 are not satisfied, then as indicated in the action 801 the controller 204 continues to monitor temperature.

In FIG. 5 through FIG. 8, the various thresholds are indexed so that there is a first threshold, a second threshold, a third threshold, and so forth, the reason being that the values of these thresholds may vary among the different control flows. For example, the temperature threshold T₂, referred to as the second threshold, in the action 506 in FIG. 5 need not necessarily have the same value as the temperature threshold T₄ (referred to as the fourth threshold) in the action 704 of FIG. 7, nor need it have the same value as the temperature threshold T₃ in the action 702 of FIG. 7. However, for some embodiments it could be that some of these values are the same. For example, it is not always a requirement that the temperature threshold T₂ in the action 506 have a different value than that of the temperature threshold T₄ of the action 704.

Furthermore, although various actions in FIG. 5 through FIG. 8 make use of strictly greater than or strictly less than comparisons, due to finite precision arithmetic, these comparisons could just as well not be strict inequalities. That is, for some embodiments, an action such as the action 802 can be replaced with the essentially equivalent action in which a determination is made as to whether the skin temperature is greater than or equal to the fifth threshold. This merely implies a redefining of the value of the fifth threshold. Similar statements apply to the other actions involving inequalities.

As described with respect to the control flows of FIG. 5 through FIG. 8, embodiments use one or more IDTs to modulate thermal conductivity. Embodiments modulate thermal conductivity by driving one or more IDTs to alter phonon group velocities and to alter phonon-phonon and phonon-boundary interactions in a silicon die. Embodiments excite acoustic phonons with high group velocities to enhance thermal conductivity, and excite optical phonons with low group velocities to decrease thermal conductivity. For example, in silicon, longitudinal acoustic (LA) modes have a relatively high group velocity, and have a frequency in the range of 4 THz to 10 THz, whereas optical modes have a relatively low group velocity, and have a frequency in the range of 13 THz to 15 THz. Embodiments that switch between these two different resonant frequencies for the acoustic wave excitations provide for modulating thermal conductivity.

For some embodiments, temperature measurements may be averaged, so that it is to understand that in the various determinations involving temperature, a parameter indicative of an average temperature may be used.

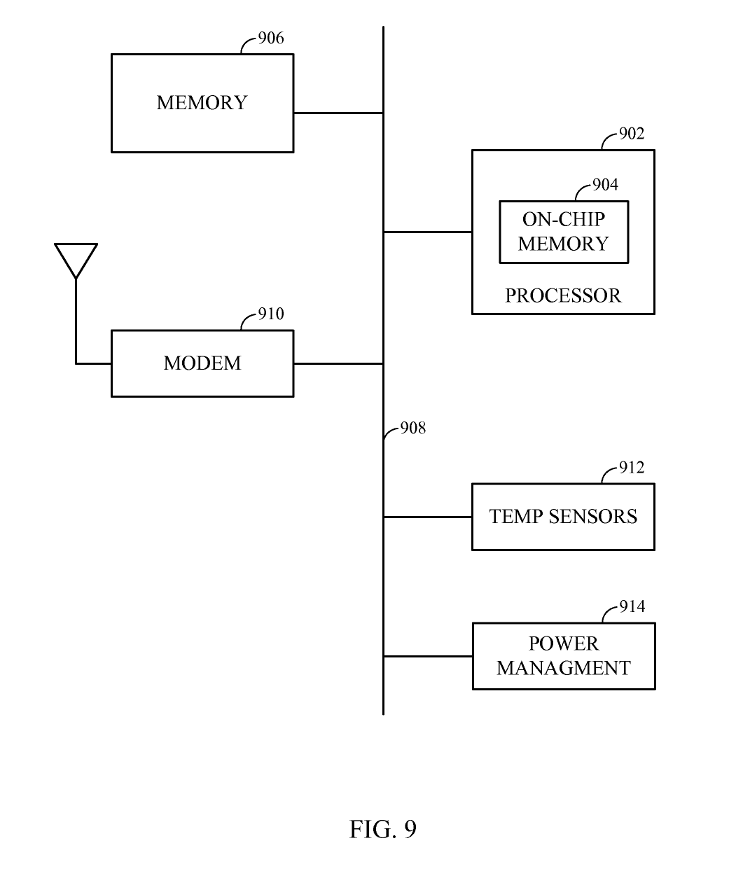

Embodiments may find applications in a wide variety of electronic systems. For example, FIG. 9 is a high-level abstraction of several components of a smartphone or tablet, and includes: the processor 902 having the on-chip memory 904, the memory 906 coupled to the processor 902 by way of the bus 908, and the modem 910. The memory 906 may belong to a memory hierarchy. Multiple processor cores residing on one or more semiconductor dice may provide the functionality of the processor 902. Embodiments may reside on the processor 902, for example, where one or more functional units in the processor 902 may implement the processes described with respect to the flow diagram of FIG. 5 through FIG. 8 by executing instructions stored on the on-chip memory 904 or the memory 906. Accordingly, the on-chip memory 904, the memory 906, as well as other memories discussed herein, may be viewed in some contexts as non-transitory computer-readable media.

Also illustrated in FIG. 9 are the power management unit 914 and a plurality of temperature sensors, which for convenience is represented by the single functional unit labeled 912. In some embodiments, the power management unit 914 may be embedded in the processor 902. A similar statement may be made regarding one or more of the temperature sensors represented by the functional unit 912. Accordingly, the representation of an individual functional unit as illustrated in FIG. 9 is not meant to imply that such a functional unit resides on a chip distinct from any other of the various illustrated functional units, so that some of the functional units illustrated in FIG. 9 may be embedded on the same chip.

Those of skill in the art will appreciate that transducers having structures other than that of an IDT may be employed to generate acoustic or optical phonons.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, or a combination of computer software and hardware. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be implemented as electronic hardware, or a combination of computer software and hardware, executed by a processor (it being understood that “processor” may include multiple processors or multiple processor cores) and electronic circuits. A software module for implementing part of an embodiment may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for enhancement of chip thermal performance through silicon thermal conductivity modulation. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A system comprising:
a silicon die having an active layer, the active layer comprising
a processor;
a power rail to provide current to the processor;
a temperature sensor to provide a signal indicative of a temperature of the processor; and
at least one functional unit;
at least one transducer; and
a controller to drive the at least one transducer to excite acoustic phonons or optical phonons in the silicon die.

2. The system of claim 1, the controller configured to:
drive the at least one transducer to excite acoustic phonons in a region in the silicon die overlapping the at least one functional unit provided the at least one functional unit is in a power collapse state, the signal indicates the temperature of the processor is greater than a first threshold, and a current in the power rail is greater than a second threshold.

3. The system of claim 2, wherein the region does not overlap the processor.

4. The system of claim 3, the controller configured to drive the at least one transducer to excite acoustic phonons in the region to increase thermal conductivity in the region.

5. The system of claim 1, wherein the signal indicates an average of temperature values.

6. The system of claim 1, wherein the controller and the at least one transducer are integrated in the silicon die, wherein the at least one transducer comprises an inter-digital transducer.

7. The system of claim 1, wherein the at least one functional unit is selected from the group consisting of a modem, a graphics processor unit, and multi-media sub-system.

8. The system of claim 1, further comprising:
a memory stacked on the silicon die; and
a second temperature sensor to provide a second signal indicative of a temperature of the memory;
the controller configured to drive the at least one transducer to excite optical phonons throughout the silicon die provided the signal indicates that the temperature of the processor is less than a first threshold and the second signal indicates that a temperature of the memory is greater than a second threshold.

9. The system of claim 8, the controller configured to drive the at least one transducer to excite optical phonons to decrease thermal conductivity in the silicon die.

10. The system of claim 1, further comprising:
a packaged integrated circuit, the packaged integrated circuit having a surface temperature and comprising the silicon die; and
a second temperature sensor to provide a second signal indicative of the surface temperature;
the controller configured to drive the at least one transducer to excite optical phonons throughout the silicon die provided the signal indicates that the temperature of the processor is less than a first threshold and the second signal indicates that surface temperature is greater than a second threshold.

11. The system of claim 10, the controller configured to drive the at least one transducer to excite optical phonons to decrease thermal conductivity in the silicon die.

12. A method to modulate thermal conductivity in a silicon die having an active layer with a processor and at least one functional unit, the method comprising:
driving at least one transducer to excite acoustic phonons in a region in the silicon die overlapping the at least one functional unit provided the at least one functional unit is in a power collapse state, a signal indicates a temperature of the processor is greater than a first threshold, and a current in a power rail to the processor is greater than a second threshold.

13. The method of claim 12, wherein the region does not overlap the processor.

14. The method of claim 13, the method further comprising:
increasing thermal conductivity of the silicon die in the region in response to the signal indicating the temperature of the processor is greater than the first threshold.

15. The method of claim 12, further comprising:
averaging temperatures associated with the processor so that the signal indicates an average of the temperatures.

16. The method of claim 12, wherein the at least one transducer is integrated in the silicon die and comprises an inter-digital transducer.

17. The method of claim 12, wherein the at least one functional unit is selected from the group consisting of a modem, a graphics processor unit, and multi-media sub-system.

18. The method of claim 12, further comprising:
driving the at least one transducer to excite optical phonons throughout the silicon die provided the signal indicates that the temperature of the processor is less than a first threshold and a second signal indicates that a temperature of a memory stacked on the silicon die is greater than a second threshold.

19. The method of claim 18, further comprising:
decreasing thermal conductivity of the silicon die in response to the signal indicating the temperature of the processor is less than a first threshold and the second signal indicating the temperature of the memory is greater than the second threshold.

20. The method of claim 12, further comprising:
driving the at least one transducer to excite optical phonons throughout the silicon die provided the signal indicates that the temperature of the processor is less than a first threshold and a second signal indicates that a surface temperature of a packaged integrated circuit comprising the silicon die is greater than a second threshold.

21. The method of claim 20, further comprising:
decreasing thermal conductivity of the silicon die in response to the signal indicating the temperature of the processor is less than the first threshold and the second signal indicating the surface temperature is greater than the second threshold.

22. A non-transitory computer-readable media storing instructions to program a controller to modulate thermal conductivity of a silicon die, the silicon die having an active layer comprising a processor, a power rail to provide current to the processor, a temperature sensor to provide a signal indicative of a temperature of the processor, and at least one functional unit, the stored instructions when executed by the controller to perform a method comprising:
driving at least one transducer to excite acoustic phonons in a region in the silicon die overlapping the at least one functional unit but not overlapping the processor provided the at least one functional unit is in a power collapse state, the signal indicates the temperature of the processor is greater than a first threshold, and the current in the power rail to the processor is greater than a second threshold.

23. The non-transitory computer-readable media of claim 22, the method performed by the controller further comprising:
driving the at least one transducer to excite optical phonons throughout the silicon die provided the signal indicates that the temperature of the processor is less than a first threshold and a second signal indicates that a temperature of a memory stacked on the silicon die is greater than a second threshold; and
driving the at least one transducer to excite optical phonons throughout the silicon die provided the signal indicates that the temperature of the processor is less than a first threshold and a third signal indicates that a surface temperature of a packaged integrated circuit comprising the silicon die is greater than a second threshold.

24. A system comprising:
a silicon die having an active layer, the active layer comprising
a processor;
a power rail to provide current to the processor;
a temperature sensor means for providing a signal indicative of a temperature of the processor; and
at least one functional unit;
an exciter means for exciting acoustic phonons or optical phonons in the silicon die; and
a controller means for controlling the exciter means.

25. The system of claim 24, the controller means configured to:
control the exciter means to excite acoustic phonons in a region in the silicon die overlapping the at least one functional unit provided the at least one functional unit is in a power collapse state, the signal indicates the temperature of the processor is greater than a first threshold, and a current in the power rail is greater than a second threshold.

26. The system of claim 25, wherein the region does not overlap the processor.

27. The system of claim 24, wherein the signal indicates an average of temperature values.

28. The system of claim 24, further comprising:
a memory stacked on the silicon die; and
a second temperature sensor means for providing a second signal indicative of a temperature of the memory;
the controller means configured to control the exciter means to excite optical phonons throughout the silicon die provided the signal indicates that the temperature of the processor is less than a first threshold and the second signal indicates that a temperature of the memory is greater than a second threshold.

29. The system of claim 24, further comprising:
a packaged integrated circuit, the packaged integrated circuit having a surface temperature and comprising the silicon die; and
a second temperature sensor means for providing a second signal indicative of the surface temperature;
the controller means configured to control the exciter means to excite optical phonons throughout the silicon die provided the signal indicates that the temperature of the processor is less than a first threshold and the second signal indicates that surface temperature is greater than a second threshold.

30. The system of claim 24, wherein the at least one functional unit is selected from the group consisting of a modem, a graphics processor unit, and multi-media sub-system.
